(19) United States
(12) Patent Application Publication
(10) Pub. No.: US 2018/0358241 A1
(43) Pub. Date: Dec. 13, 2018

(54) SUBSTRATE TREATING APPARATUS AND METHODS

(71) Applicant: Samsung Electronics Co., Ltd., Suwon-si (KR)

(72) Inventors: Hyunwook LEE, Hwaseong-si (KR); Gunbo Kang, Yongin-si (KR); Yongmog Kim, Suwon-si (KR)

(73) Assignee: Samsung Electronics Co., Ltd., Suwon-si (KR)

(21) Appl. No.: 15/841,909

(22) Filed: Dec. 14, 2017

(30) Foreign Application Priority Data
Jun. 8, 2017 (KR) 10-2017-0071826

(51) Int. Cl. H01L 21/67; H01L 21/02; H01L 21/687

(52) U.S. Cl. CPC H01L 21/67023; H01L 21/02052; H01L 21/687; H01L 21/02019; H01L 21/6708

(57) ABSTRACT

Substrate treating apparatus and methods are provided. The substrate treating method may include supplying a first side of a substrate with a first chemical solution from a first supply unit, supplying a second side of the substrate with a second chemical solution from a second supply unit, collecting a third chemical solution into a collect vessel, supplying the second supply unit with the third chemical solution to store a fourth chemical solution in the second supply unit, supplying the first side of the substrate with the first chemical solution stored in the first supply unit, and supplying the second side of the substrate with the fourth chemical solution stored in the second supply unit. The third chemical solution may be a mixture of the first and second chemical solutions. The fourth chemical solution may be a mixture of the second and third chemical solutions.

### CROSS-REFERENCE TO RELATED APPLICATIONS

This U.S. non-provisional patent application claims priority under 35 U.S.C. § 119 of Korean Patent Application No. 10-2017-0071826 filed on Jun. 8, 2017 entire contents of which are hereby incorporated by reference.

### BACKGROUND

The present inventive concepts relate to substrate treating apparatus and methods, and more particularly, single-wafer type substrate treating apparatus and methods.

In general, as semiconductor devices are developed to high density, increased integration, and excellent performance, fineness of patterns are rapidly progressing. Semiconductor devices may be affected by contaminants such as particles, organic pollutions, and metallic pollutions remaining on a substrate surface. Accordingly, a cleaning process for removing various contaminant or unnecessary layers attached onto the substrate surface may be done when manufacturing semiconductor devices.

A cleaning process used in manufacturing semiconductor devices is broadly classified into a dry cleaning and a wet cleaning. The wet cleaning includes a bath type, in which chemical dissolution is used to remove contaminant from a substrate immersed in a chemical solution, and a single-wafer type, in which a chemical solution is sprayed to remove contaminants from a surface of a substrate that is rotating on a support chuck.

A single-wafer type cleaning apparatus may use various kinds of cleaning solutions based on types of contaminants and layers. In recent years, a new single-wafer type cleaning apparatus capable of recycling cleaning solutions has been developed, and may be applied to the semiconductor fabrication facility.

### SUMMARY

Some embodiments of provide substrate treating methods that enhance yield of semiconductor devices.

Some embodiments of the present inventive concepts provide substrate treating apparatuses that enhance yield of semiconductor devices.

Features and/or effects of the present inventive concepts are not limited to those discussed above, and other features and/or effects may be clearly understood to those skilled in the art from the following description.

According to some example embodiments of the present inventive concepts, a substrate treating method may include supplying a first side of a substrate with a first chemical solution from a first supply unit; supplying a second side of the substrate with a second chemical solution from a second supply unit; collecting a third chemical solution into a collect vessel, the third chemical solution being a mixture of the first chemical solution and the second chemical solution; supplying the second supply unit with the third chemical solution to store a fourth chemical solution in the second supply unit, the fourth chemical solution being a mixture of the second chemical solution and the third chemical solution; supplying the first side of the substrate with the first chemical solution from the first supply unit; and supplying the second side of the substrate with the fourth chemical solution from the second supply unit.

According to some example embodiments of the present inventive concepts, a substrate treating method may include supplying a first side of a substrate with a first chemical solution; supplying a second side of the substrate with a second chemical solution; and collecting the first chemical solution and the second chemical solution into a collect vessel. The first chemical solution and the second chemical solutions may be a same kind of chemical solution. A purity of the first chemical solution may be different than a purity of the second chemical solution.

According to some example embodiments of the present inventive concepts, a substrate treating apparatus may include a first supply unit, a second supply unit, and a substrate treating unit. The substrate treating unit may include a support chuck that is configured to support a substrate, a first nozzle arranged to face a front side of the substrate, a second nozzle arranged to face a back side of the substrate, and a collect vessel that lies on an edge of the support chuck and is configured to collect a chemical solution. The first supply unit may be engaged with the first nozzle through a first supply line and may be configured to provide the first nozzle with a chemical solution from the first supply unit. The second supply unit may be engaged with the second nozzle through a second supply line and may provide the second nozzle with a chemical solution stored in the second supply unit. The second supply unit may be engaged with the collect vessel through a collect line, and may be configured to receive the chemical solution collected into the collect vessel.

### BRIEF DESCRIPTION OF THE DRAWINGS

FIG. 1 illustrates a cross-sectional view showing a substrate treating apparatus according to some example embodiments of the present inventive concepts.

FIG. 2 illustrates a flow chart showing a substrate treating method according to some example embodiments of the present inventive concepts.

FIG. 3 illustrates a cross-sectional view showing a substrate treating apparatus according to some example embodiments of the present inventive concepts.

### DETAILED DESCRIPTION

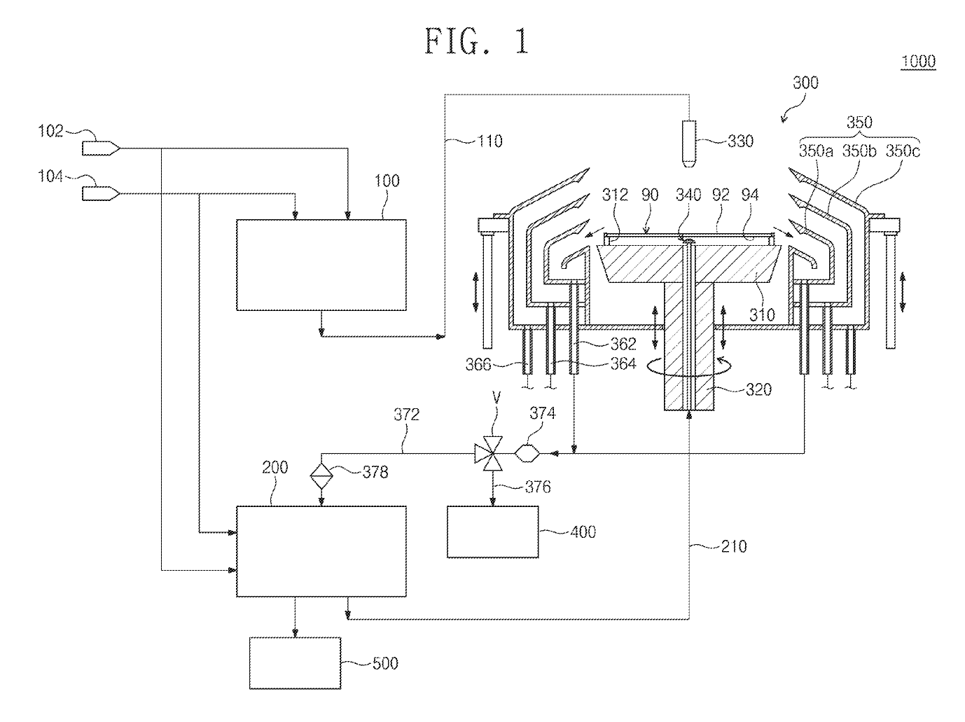

FIG. 1 illustrates a cross-sectional view showing a substrate treating apparatus according to some example embodiments of the present inventive concepts.

A substrate treating apparatus 1000 may include a first supply unit 100 (e.g., manifold), a second supply unit 200 (e.g., manifold), and a substrate treating unit 300. The first supply unit 100 may be connected to a chemical solution supply source 102 and a rinse solution supply source 104 (e.g., piping connected to chemical container). The second supply unit 200 may be connected to the chemical solution supply source 102 (e.g., piping connected to chemical container) and the rinse solution supply source 104. In some embodiments, the chemical solution supply source 102 may supply a chemical solution such as an etching solution and a cleaning solution, and the rinse solution source 104 may supply deionized water. Each of the first and second supply units 100 and 200 may receive and mix the chemical solution and the deionized water supplied from chemical solution supply source 102 and the rinse solution supply source 104, respectively.

The substrate treating unit 300 may include a support chuck 310, a drive shaft 320, a first nozzle 330, a second nozzle 340, and a collect vessel 350. A substrate 90 may be provided on the support chuck 310. The support chuck 310 may include chucking pins 312 The chucking pins 312 may be disposed on a top surface of the support chuck 310, and the substrate 90 may be fixedly loaded through the chucking pins 312 on the support chuck 310. The chucking pins 312 may be equally arranged along a circumference of the substrate 90. The drive shaft 320 may be disposed on a bottom surface of the support chuck 310. The drive shaft 320 may be associated with the support chuck 310. The drive shaft 320 may be provided with a driving mechanism (not shown) including a motor. The driving mechanism may drive the drive shaft 320 to rotate the support chuck 310 at a desired (and/or alternatively predetermined) speed during the time when a process is performed. In addition, the driving mechanism may drive the drive shaft 320 to move the support chuck 310 in an up-and-down direction.

The first nozzle 330 may be placed on a first side 92 of the substrate 90. The first nozzle 330 may be fixedly held on the support chuck 310. The first nozzle 330 may be engaged with the first supply unit 100 through a first supply line 110. The first supply unit 100 may supply a chemical solution to the first nozzle 330 by which the chemical solution may be sprayed onto the first side 92 of the substrate 90. In some embodiments, when a chemical solution is sprayed onto a center of the first side 92 of the substrate 90, the chemical solution may flow outward to an edge of the substrate 90 due to the centrifugal force produced by rotation of the substrate 90. Accordingly, the chemical solution may etch or clean an entirety of the first side 92 of the substrate 90.

The second nozzle 340 may be placed on a second side 94 opposite the first side 92 of the substrate 90. The second nozzle 340 may be placed in a space between the support chuck 310 and the second side 94 of the substrate 90. A portion of the second nozzle 340 may be disposed in the support chuck 310 and the drive shaft 320. The second nozzle 340 may be engaged with the second supply unit 200 through a second supply line 210. The second supply line 210 may be mechanically separated from the first supply line 110. For example, the first and second supply lines 110 and 210 may not be connected to each other with any interconnect line. In this configuration, a chemical solution flowing through the first supply line 110 may not be mixed with a chemical solution flowing through the second supply line 210. Chemical solutions flowing through the first and second supply lines 110 and 210 may not be supplied from the same supply unit or reservoir. A chemical solution supplied from the second supply unit 200 may flow through the second supply line 210 into the second nozzle 340 by which the chemical solution may be sprayed onto the second side 94 of the substrate 90. In some embodiments, when a chemical solution is sprayed onto a center of the second side 94 of the substrate 90, the chemical solution may flow outward an edge of the substrate 90 due to the centrifugal force produced by rotation of the substrate 90. Accordingly, the chemical solution may etch or clean an entirety of the second side 94 of the substrate 90.

The collect vessel 350 may be disposed on an edge of the support chuck 310. The collect vessel 350 may include a first collect barrel 350a, a second collect barrel 350b, and a third barrel 350c. The second collect barrel 350b may surround an outer wall of the first collect barrel 350a, and the third collect barrel 350c may surround an outer wall of the second collect barrel 350b. The first collect barrel 350a may have a first space defined by an inner wall of the first collect barrel 350a. The second collect barrel 350b may be spaced apart from the first collect barrel 350a at a desired (and/or alternatively predetermined) spacing, and may have a second space defined by the outer wall of the first collect barrel 350a and an inner wall of the second collect barrel 350b. The third collect barrel 350c may be spaced apart from the second collect barrel 350b at a desired (and/or alternatively predetermined) spacing, and may have a third space defined by the outer wall of the second collect barrel 350b and an inner wall of the third collect barrel 350c.

The first to third collect barrels 350a, 350b, and 350c may have respective receiving entrances at different levels from each other. For example, the receiving entrance of the second collect barrel 350b may be higher than that of the first collect barrel 350a, and the receiving entrance of the third collect barrel 350c may be higher than that of the second collect barrel 350b.

In some embodiments, as discussed above, as the support chuck 310 moves in the up-and-down direction, the support chuck 310 may have a placement height that is variable based on processing operations. For example, in a first substrate treatment operation, the support chuck 310 may be placed at a height corresponding to that of the receiving entrance of the first collect barrel 350a, and the first collect barrel 350a may collect a chemical solution that has been used in the first substrate treatment operation. In a second substrate treatment operation that uses another chemical solution different from that used in the first substrate treatment operation, the support chuck 310 may move upward to be placed at a height corresponding to that of the receiving entrance of the second collect barrel 350b. The second collect barrel 350b may collect a chemical solution that has been used in the second substrate treatment operation.

In other embodiments, the support chuck 310 may be fixedly disposed, while the collect vessel 350 may be configured to move in the up-and-down direction. In this case, the collect vessel 350 may move based on process operations for substrate treatment, and each receiving entrance of the first to third collect barrels 350a, 350b, and 350c may move to be placed at a height corresponding to that of the support chuck 310.

The first collect barrel 350a may be connected to a first exhaust line 362 that discharges a chemical solution collected in the first collect barrel 350a, and the second collect barrel 350b may be connected to a second exhaust line 364 that discharges a chemical solution collected in the second collect barrel 350b. Likewise, the third collect barrel 350c may be connected to a third exhaust line 366 that discharges a chemical solution collected in the third collect barrel 350c.

One or more of the first to third exhaust lines 362, 364, and 366 may be engaged with a three-way valve V. In some embodiments, the first exhaust line 362 may be engaged with the three-way valve V. The first exhaust line 362 may be connected through the three-way valve V to a collect line 372 and a drain line 376. The three-way valve V may be coupled to a branch point between the collect line 372 and the drain line 376. The three-way valve V may open the collect line 372 and close the drain line 376, depending on whether or not chemical solutions are recyclable. For example, the three-way valve V may operate such that recyclable chemical solutions may flow through the collect line 372 and non-recyclable chemical solutions may flow through the drain line 376. The non-recyclable chemical solutions may be wasted through the drain line 376 to a first waste unit 400 (e.g., tank).

The substrate treating apparatus 1000 may further include a control unit (not shown) that controls operation of the three-way valve V. The control unit may determine whether or not chemical solutions flowing through the first exhaust line 362 are recyclable, and based on the determination result, may provide the three-way valve V with a control signal that selectively opens one of the collect line 372 and the drain line 376, thereby controlling operation of the three-way valve V. One or more of the first to third exhaust lines 362, 364, and 366 may not be engaged with the three-way valve V, wasting chemical solutions through waste lines (not shown). In some embodiments, the second and third exhaust lines 364 and 366 may be connected to the waste lines (not shown), and chemical solutions collected in the second and third collect barrels 350b and 350c may be wasted through the waste lines.

A concentration meter 374 may be installed between the three-way valve V and the first exhaust line 362. The concentration meter 374 may have a function to measure a concentration of impurities contained in chemical solutions flowing through the first exhaust line 362. The concentration meter 374 may include at least one of power supply circuit, a transducer circuit, a transmitter circuit, or a sensor circuit. In some embodiments, a filter 378 may be installed between the second supply unit 200 and the three-way valve V. The filter 378 may have a function to filter impurities (not shown) remaining in chemical solutions flowing through the collect line 372. The present inventive concepts are not limited to those illustrated in figures, and the substrate treating apparatus 1000 may be provided without one or more of the concentration meter 374 and the filter 378. The concentration meter 374 and the filter 378 may be installed in various places.

The second supply unit 200 may be engaged with a second waste unit 500 (.e.g., tank). When the second supply unit 200 stores a chemical solution whose level exceeds a first height from a floor surface of the second supply unit 200, the second waste unit 500 may receive a portion of the chemical solution from the second supply unit 200. As such, the second supply unit 200 may accommodate an appropriate amount of the chemical solution.

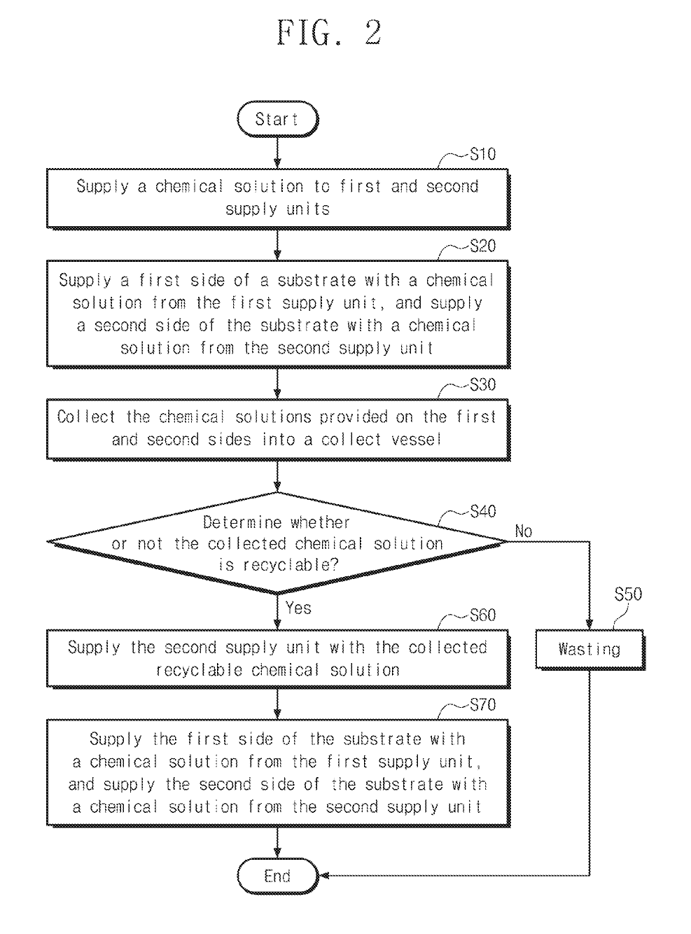

FIG. 2 illustrates a flow chart showing a substrate processing method according to some example embodiments of the present inventive concepts.

Referring to FIGS. 1 and 2, the first and second supply units 100 and 200 may each be supplied with a chemical solution (S10). For example, the first supply unit 100 may be supplied with a first chemical solution, and the second supply unit 200 may be supplied with a second chemical solution. The first and second chemical solutions may each be a mixture of a treatment chemical solution supplied from the chemical solution supply source 102 and deionized water supplied from the rinse solution supply source 104. For example, the treatment chemical solution may be a cleaning solution or an etching solution. The first and second chemical solutions may be the same kind of chemical solution. The first and second chemical solutions may have the same purity. The first and second chemical solutions may be SCI (Standard Cleaning 1 or APM (Ammonium Peroxide Mixture), an organic mixture of NH₄OH:H₂O₂:H₂O with a ratio of 1:1:5 to 1:4:20), HF, BOE, or DSP (Diluted Sulfate Peroxide including sulfuric acid, hydrogen peroxide, water, and fluoric acid).

The first side 92 may receive a chemical solution supplied from the first supply unit 100, and the second side 94 may receive a chemical solution supplied from the second supply unit 200 (S20). For example, the first side 92 may be supplied with the first chemical solution, and the second side 94 may be supplied with the second chemical solution. The first chemical solution stored in the first supply unit 100 may be provided through the first supply line 110 to the first nozzle 330, and may then be sprayed through the first nozzle 330 onto the first side 92 of the substrate 90. In some embodiments, the first side 92 of the substrate 90 may be a side that has experienced a patterning process including deposition or etching and is then cleaned. For example, the first side 92 of the substrate 90 may be a front side. The second chemical solution stored in the second supply unit 200 may be provided through the second supply line 210 to the second nozzle 340, and then sprayed through the second nozzle 340 onto the second side 94 of the substrate 90. In some embodiments, the second side 94 of the substrate 90 may be an opposite side to the first side 92. For example, the second side 94 may be a back side. The first chemical solution may be used to remove impurities from the first side 92 of the substrate 90, or to etch or pattern a deposition layer formed on the first side 92 of the substrate 90. The second chemical solution may be used to remove impurities from the second side 94 of the substrate 90.

In some embodiments, the first chemical solution provided on the first side 92 of the substrate 90 may change in purity from a first purity to a second purity that may be different than the first purity. The first chemical solution may have a variable purity based on its mixture with impurities present or formed on the first side 92 of the substrate 90. For example, the second purity may be less than the first purity. The second chemical solution provided on the second side 94 of the substrate 90 may change in purity from a third purity to a fourth purity that may be different than the third purity. The second chemical solution may have a variable purity based on its mixture with impurities present or formed on the second side 94 of the substrate 90. For example, the fourth purity may be less than the third purity. For example, a larger amount of impurities may be present on the first side 92 of the substrate 90 than on the second side 94 of the substrate 90. Accordingly, the second purity of the first chemical solution may be less than the fourth purity of the second chemical solution.

During the time when the first and second chemical solutions are respectively sprayed onto the first and second sides 92 and 94 of the substrate 90, the support chuck 310 may rotate at a height corresponding to that of the receiving entrance of one of the first to third collect barrels 350a, 350b, and 350c. For example, the support chuck 310 may rotate at a height corresponding to that of the receiving entrance of the first collect barrel 350a.

In some embodiments, during the time when the first and second chemical solutions are respectively sprayed onto the first and second sides 92 and 94 of the substrate 90, the first and second chemical solutions may be continuously supplied to the first and second supply units 100 and 200, respectively.

Any one of the first to third collect barrels 350a, 350b, and 350c may collect chemical solutions sprayed on the first and second sides 92 and 94 of the substrate 90 (S30). For example, any one of the first to third collect barrels 350a, 350b, and 350c may collect the first and second chemical solutions that are sprayed onto the first and second sides 92 and 94 of the substrate 90. The first and second chemical solutions may flow outward to the edge of the substrate 90 from a center of the substrate 90 due to the centrifugal force produced by rotation of the support chuck 310, and may then be collected into the collect vessel 350 disposed on the edge of the support chuck 310. For example, the first collect barrel 350a may collect through its receiving entrance the first and second chemical solutions. Thus, the first collect barrel 350a may receive a third chemical solution, or a mixture of the first and second chemical solutions. The third chemical solution may be the same material as those of the first and second chemical solutions. In some embodiments, the third chemical solution may have purity different from the first purity of the first chemical solution and the third purity of the second chemical solution. For example, the purity of the third chemical solution may be less than the first purity of the first chemical solution and the third purity of the second chemical solution. Alternatively, the purity of the third chemical solution may be less than the first purity of the first chemical solution and greater than the third purity of the second chemical solution. Dissimilarly, the purity of the third chemical solution may be less than the first purity of the first chemical solution and equal to the third purity of the second chemical solution.

The purity of the third chemical solution may correspond to an average of the second purity of the first chemical solution and the fourth purity of the second chemical solution. For example, the purity of the third chemical solution may be determined based on the second purity of the first chemical solution and the fourth purity of the second chemical solution. During the time when one substrate experiences an etching or cleaning process, the purity of the third chemical solution may increase as the process continues. As the process continues, an amount of impurities may decrease on the first and second sides 92 and 94 of the substrate 90, thereby increasing the purity of the third chemical solution. For example, during the time when one substrate experiences an etching or cleaning process, purity of the third chemical solution collected at a later time of the process may be greater than purity of the third chemical solution collected at an earlier time of the process.

In some embodiments, during the time when the first and second chemical solutions are collected into the first collect barrel 350a, the first and second chemical solutions may be continuously sprayed onto the first and second sides 92 and 94, respectively, of the substrate 90.

Chemical solutions collected into collect barrels may be determined whether or not recyclable (S40). For example, the third chemical solution collected into the first collect barrel 350a may be discharged through the first exhaust line 362, and may then be determined whether or not recyclable.

In some embodiments, the third chemical solution may be discharged from the first collect barrel 350a through the first exhaust line 362, and then a concentration of impurities contained in the third chemical solution may be measured by the concentration meter 374 installed between the three-way valve V and the first exhaust line 362. For example, when the impurity concentration of the third chemical solution does not satisfy a concentration criterion range, it may be determined that the third chemical solution is contaminated, and thereby the third chemical solution may be wasted through the drain line 376 to the first waste unit 400 (S50). For example, the wasted third chemical solution may have purity of less than about 50%. In this case, the three-way valve V may receive a signal from the control unit (not shown) that controls operation of the three-way valve V, and may then operate allowing the third chemical solution to flow to the drain line 376. When the impurity concentration of the third chemical solution satisfies the concentration criterion range, it may be determined that the third chemical solution is not yet contaminated, and thereby the third chemical solution may be supplied (and/or received) through the collect line 372 back to the second supply unit 200 (S60). For example, the third chemical solution supplied back to the second supply unit 200 may have purity ranging from about 50% to about 99.8%. In this case, the three-way valve V may receive from the control unit (not shown) a signal to allow the third chemical solution to flow to the collect line 372. The third chemical solution supplied back to the second supply unit 200 may mix with the second chemical solution stored in the second supply unit 200. Accordingly, the second supply unit 200 may store a fourth chemical solution, or a mixture of the second and third chemical solutions.

In other embodiments, determination of recycling of the third chemical solution may be achieved by a preset recipe that operates the three-way valve V to selectively open one of the collect line 372 and the drain line 376. The recipe may be prepared or set in the control unit (not shown) engaged with the three-way valve V, and the control unit may operate through the recipe to drive the three-way valve V. For example, if one substrate experiences an etching or cleaning process, and if it is known the third chemical solution has a suitable purity for recycling at a certain time after the process is performed, the recipe may correspond to the certain time from the start of the process. The three-way valve V may operate to open the drain line 376 before the certain time from the start of the process, and to open the collect line 372 after the certain time from the start of the process. Therefore, the third chemical solution may flow into the first waste unit 400 during the time when the drain line 376 is open, and may flow into the second supply unit 200 during the time when the collect line 372 is open. In this case, differently from that shown in figures, the concentration meter 374 may not be installed between the three-way valve V and the first exhaust line 362.

In some embodiments, the third chemical solution may be continuously collected into the first collect barrel 350a during the time when the third chemical solution is determined whether or not recyclable. In addition, during the time when the third chemical solution is wasted or supplied back to the second supply unit 200 after the determination of recycling of the third chemical solution, the determinate of recycling may be continuously performed on the third chemical solution collected into the first collect barrel 350a.

In some embodiments, the filter 378 may be installed between the second supply unit 200 and the three-way valve V. The filter 378 may filter impurities contained in the third chemical solution flowing through the collect line 372.

The first side 92 may receive a chemical solution supplied from the first supply unit 100, and the second side 94 may receive a chemical solution supplied from the second supply unit 200 (S70). For example, the first chemical solution may be provided onto the first side 92 of the substrate 90, and the fourth chemical solution may be provided onto the second side 94 of the substrate 90. The first chemical solution may be re-supplied through the first supply line 110 to the first nozzle 330, and the fourth chemical solution may be re-supplied through the second supply line 210 to the second nozzle 340. The fourth chemical solution stored in the second supply unit 200 may not mix with the first chemical solution stored in the first supply unit 100. For example, the fourth chemical solution may not be supplied to the first supply unit 100. The fourth chemical solution may include the third chemical solution that is collected after treating the first and second sides 92 and 94 of the substrate 90, and thus the fourth chemical solution may have purity less than the first purity of the first chemical solution.

In some embodiments, during the time when the first and fourth chemical solutions are respectively provided onto the first and second sides 92 and 94 of the substrate 90, if (and/or in response to) the fourth chemical solution is determined to be recyclable, the fourth chemical solution may be continuously collected and then supplied back to the second supply unit 200.

According to some example embodiments of the present inventive concepts, the recyclable chemical solution may be selectively provided on the non-patterned second side 94 of the substrate 90, and thereby it may be possible to limit and/or prevent semiconductor devices from suffering yield reduction caused when the recyclable chemical solution is provided on the patterned first side 92 of the substrate 90.

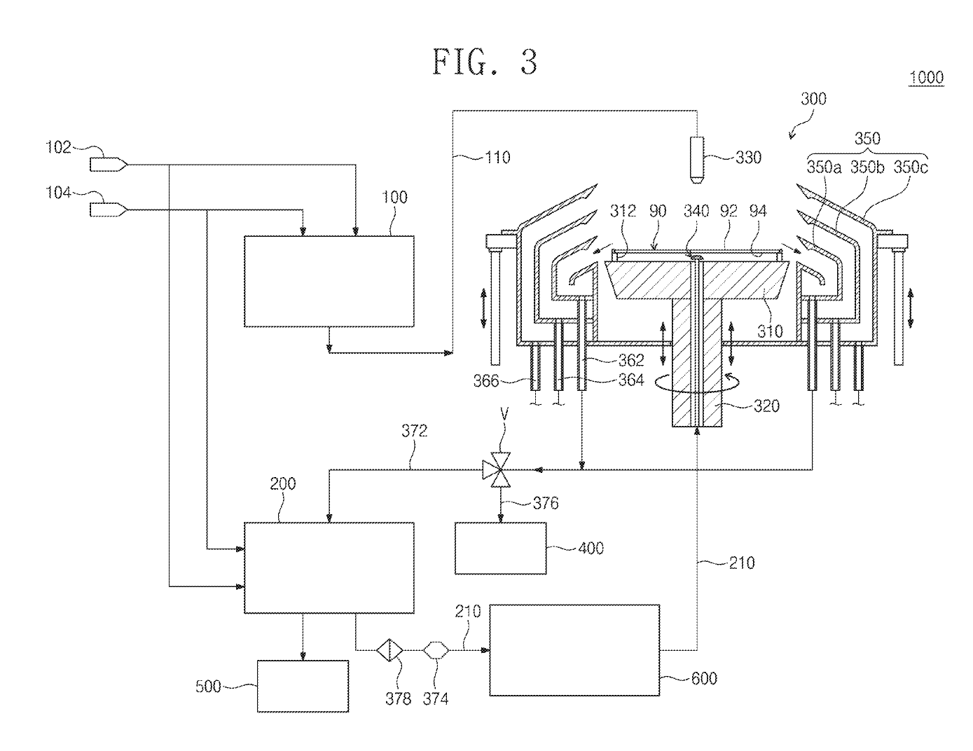

FIG. 3 illustrates a cross-sectional view showing a substrate processing apparatus according to some example embodiments of the present inventive concepts. For brevity of description, components substantially the same as those of the substrate treating apparatus discussed with reference to FIG. 1 are allocated the same reference numerals thereto, and a repetitive explanation thereof will be omitted.

Referring to FIG. 3, a reservoir 600 may be disposed between the second supply unit 200 and the second nozzle 340. The reservoir 600 may be engaged through the second supply line 210 with the second supply unit 200 and the second nozzle 340. The recyclable fourth chemical solution stored in the second supply unit 200 may be supplied not directly but through the reservoir 600 to the second nozzle 340. The reservoir 600 may keep the fourth chemical solution at constant temperature and pressure, and may remove bubbles contained in the fourth chemical solution. In addition, the reservoir 600 may maintain a constant supply amount of the fourth chemical solution flowing into the second nozzle 340.

In some embodiments, the concentration meter 374 and the filter 378 may be installed between the second supply unit 200 and the reservoir 600.

According to some example embodiments of the present inventive concepts, a recyclable chemical solution may be selectively provided on a non-patterned back side of a substrate, and thereby it may be possible to limit and/or prevent semiconductor devices from suffering yield reduction caused when the recyclable chemical solution is provided on a patterned front side of the substrate.

Furthermore, as the recyclable chemical solution is used to treat the back side of the substrate, the chemical solution may decrease in total use and waste amounts.

Although the present inventive concepts have been described in connection with the embodiments of the present invention illustrated in the accompanying drawings, it will be understood to those skilled in the art that various changes and modifications may be made without departing from the technical spirit and features of the present inventive concepts. It will be apparent to those skilled in the art that various substitution, modifications, and changes may be thereto without departing from the scope and spirit of the claims.

What is claimed is:

1. A substrate treating method comprising:
supplying a first side of a substrate with a first chemical solution from a first supply unit;
supplying a second side of the substrate with a second chemical solution from a second supply unit;
collecting a third chemical solution into a collect vessel, the third chemical solution being a mixture of the first chemical solution and the second chemical solution;
supplying the second supply unit with the third chemical solution to store a fourth chemical solution in the second supply unit, the fourth chemical solution being a mixture of the second and third chemical solutions;
supplying the first side of the substrate with the first chemical solution from the first supply unit; and
supplying the second side of the substrate with the fourth chemical solution from the second supply unit.

2. The method of claim 1, wherein
the first side of the substrate is a front side of the substrate, and
the second side of the substrate is a back side of the substrate.

3. The method of claim 1, wherein
the first chemical solution, the second chemical solution, the third chemical solution, and the fourth chemical solution are a same kind of chemical solution, and
a purity of the first chemical solution and a purity of the second chemical solution are the same.

4. The method of claim 3, wherein a purity of the third chemical solution less than the purity of the first chemical solution and the purity of the second chemical solution.

5. The method of claim 1, further comprising:
determining whether or not the third chemical solution is recyclable, wherein
the determining whether or not the third chemical solution is recyclable includes measuring a concentration of impurities contained in the third chemical solution, and
the determining whether or not the third chemical solution is recyclable is performed before the supplying the second supply unit with the third chemical solution.

6. The method of claim 1, further comprising:
the determining whether or not the third chemical solution is recyclable is performed before the supplying the second supply unit with the third chemical solution,
the determining whether or not the third chemical solution is recyclable includes wasting the third chemical solution in response to a time after the supplying the first side of the substrate with the first chemical solution and the supplying the second side of the substrate with the second chemical solution being less than a certain time, and
the determining whether or not the third chemical solution is recyclable includes supplying the third chemical solution to the second supply unit in response to the time after the supplying the first side of the substrate with the first chemical solution and the supplying the second side of the substrate with the second chemical solution being after the certain time.

7. The method of claim 1, wherein,
the supplying the second supply unit with the third chemical solution is performed in response to a purity of the third chemical solution being in a ranges from about 50% to about 99.8%.

8. The method of claim 1, wherein the first chemical solution, the second chemical solution, and the third chemical solutions include one of SC1 (Standard Cleaning 1), HF, BOE, or DSP (Diluted Sulfate Peroxide).

9. The method of claim 1, wherein the fourth chemical solution is not supplied to the first supply unit.

10. The method of claim 1, further comprising:
wasting a portion of the fourth chemical solution in response to a level of the fourth chemical solution being higher than a first height from a floor surface of the second supply unit.

11. A substrate treating method comprising:
supplying a first side of a substrate with a first chemical solution;
supplying a second side of the substrate with a second chemical solution, the second chemical solution and the first chemical solution being a same kind of chemical solution, a purity of the second chemical solution being different than a purity of the first chemical solution; and
collecting the first chemical solution and the second chemical solution into a collect vessel.

12. The method of claim 11, wherein the purity of the second chemical solution is less than the purity of the first chemical solution.

13. The method of claim 11, further comprising:
after the collecting the first chemical solution and the second chemical solution into the collect vessel, storing a third chemical solution in a second supply unit by providing the second supply unit with a mixed solution including the first chemical solution and the second chemical solutions that are mixed in the collect vessel, the third chemical solution being a mixture of the mixed solution and the second chemical solution stored in the second supply unit;
providing the first chemical solution to the first side of the substrate; and
providing the third chemical solution to the second side of the substrate, wherein
the supplying the first side of the substrate includes supplying the first chemical solution from a first supply unit to the first side of the substrate, and
the supplying the second side of the substrate includes supplying the second chemical solution from the second supply unit to the second side of the substrate.

14. The method of claim 13, wherein
the purity of the second chemical solution is less than the purity of the first chemical solution, and
a purity of the mixed solution is less than that the purity of the first chemical solution.

15. The method of claim 11, wherein
the first side of the substrate is a front side of the substrate, and
the second side of the substrate is a back side of the substrate.

16. The method of claim 11, wherein the first chemical solution and the second chemical solution include one of SC1 (Standard Cleaning 1), HF, BOE, or DSP (Diluted Sulfate Peroxide).

17. The method of claim 11, further comprising:
determining whether or not a mixed solution is recyclable, wherein
the determining whether or not the mixed solution is recyclable is perform after the collecting the first chemical solution and the second chemical solution into the collect vessel, and
the mixed solution includes the first chemical solution and the second chemical solution that are mixed in the collect vessel.

18. The method of claim 17, wherein the mixed solution is recyclable in response to the mixed solution having a purity ranging from about 50% to about 99.8%.

19. A substrate treating apparatus comprising:
a substrate treating unit,
the substrate treating unit including a support chuck that is configured to support a substrate,
the substrate treating unit including a first nozzle arranged to face a front side of the substrate,
the substrate treating unit including a second nozzle arranged to face a back side of the substrate, and
the substrate treating unit including a collect vessel that lies on an edge of the support chuck and is configured to collect a chemical solution;
a first supply unit,
the first supply unit being engaged with the first nozzle through a first supply line, and
the first supply unit being configured to provide the first nozzle with a chemical solution from the first supply unit; and
a second supply unit,
the second supply unit being engaged with the second nozzle through a second supply line,
the second supply unit being configured to provide the second nozzle with a chemical solution stored in the second supply unit, and
the second supply unit being engaged with the collect vessel through a collect line and being configured to receive the chemical solution collected into the collect vessel.

20. The apparatus of claim 19, wherein the first supply line and the second supply line are mechanically separated from each other.
